(19) United States
(12) Patent Application Publication
(10) Pub. No.: US 2012/0305071 A1
(43) Pub. Date: Dec. 6, 2012

(54) SUBSTRATE HAVING A METAL FILM FOR PRODUCING PHOTOVOLTAIC CELLS

(75) Inventors: Andreas Afseth, Grenoble (FR); Volkmar Gillich, Neuhausen (DE); Josef Statti, Rielasingen (DE); Ralf Platte, Singen (DE); Stephane Antoine, Colmar (FR)

(73) Assignee: CONSTELLIUM SWITZERLAND AG, Neuhausen am Rheinfall (CH)

(21) Appl. No.: 13/511,619

(22) PCT Filed: Nov. 2, 2010
(86) PCT No.: PCT/EP2010/006658

§ 371 Date: Aug. 14, 2012

(30) Foreign Application Priority Data
Nov. 26, 2009 (EP) 09405208.1

(51) Int. Cl. B32B 3/26; H01L 31/0216

(52) U.S. Cl. 136/256; 428/319.1; 428/142

(57) ABSTRACT

The invention relates to a substrate (10) having a metal film (12) for producing photovolatic cells (30), wherein a first side of the metal film (12) is intended for arranging a photovoltaic absorber layer (18). In order to improve the chemical resistance and the corrosion resistance at elevated temperature, a protective layer (16) made of a silicon-based sol-gel paint is arranged on the second side of the metal film (12).

The invention relates to a substrate having a metal film for producing photovoltaic cells, wherein a first side of the metal film is intended for arranging a photovoltaic absorber layer. A photovoltaic cell furnished with such a substrate is a further object of the invention.

Powerful photovoltaic components such as solar cells contain for example absorber layers made from elements of groups IB, IIIA and VIA, such as alloys of copper with indium and/or gallium or aluminium and selenium and/or sulphur. One common combination of the aforementioned elements is copper-indium-gallium-(di)selenide (CIGS), and the components produced from this are often called CIGS solar cells. The CIGS absorber layer may be deposited on a substrate. It would be desirable to produce such an absorber layer on an aluminium film substrate, because aluminium film is relatively inexpensive, lightweight and flexible.

Solar cells with a CIGS absorber layer constructed on an aluminium film are known from US 2007/0000537 A1. The absorber layer deposited onto the aluminium film is annealed at a temperature of up to 600° C. for several minutes. The aluminium film is exposed to attack by chemical substances in vapour and gaseous form both while the substrate is being coated or stained with the solution-based absorber material and during the subsequent curing at elevated temperature. The natural oxide layer of the aluminium, and also oxide layers generated electrolytically, have low chemical resistance and low resistance to corrosion by the aggressive chemicals. In addition, an aluminium film becomes soft under the effect of elevated temperatures, and therefore loses some of its mechanical strength.

The object of the invention is to provide a substrate of the kind described in the introduction, which has greater chemical resistance and greater resistance to corrosion in respect of the chemicals used in the production of photovoltaic cells than substrates known from the prior art. The substrate should also be easy and inexpensive to produce.

A contributory element in the solution to the object according to the invention is the fact that a protective layer made of a silicon-based sol-gel paint is arranged on the second side of the metal film in order to improve its chemical resistance and corrosion resistance at elevated temperature.

The first side of the metal film is preferably polished by high gloss rolling and/or electrolytically to achieve a surface roughness Ra<100 nm (nanometres), preferably Ra<50 nm.

In the dried and cured state the protective layer preferably has a thickness between about 0.5 and 4 μm.

The metal film is preferably a film made from aluminium or an aluminium alloy. Besides its chemical resistance, the protective layer of sol-gel paint has the further advantage of supporting and lending improved mechanical stability to the aluminium film, which softens under the effect of elevated temperatures.

The protective layer that is arranged directly on the metal film, particularly a film made from aluminium or an aluminium alloy, is a sol-gel paint that is obtained from a sol-gel system that is applied directly to the metal film.

The term gel is used to describe dimensionally stable, easily deformable dispersed systems with a high liquid content that consist of a solid, irregular, three-dimensional network and a liquid. Similarly, a sol-gel system is understood to refer to a sol-gel paint produced using sol-gel technology that, after application and curing as appropriate for the product, forms a cured, protective layer that is permanently bonded to the substrate—in this case a metal film. The layer is preferably a sol-gel paint that is transparent after curing and allows the coloured base shade of the substrate to show through. A transparently cured sol-gel paint is particularly understood to mean a clear, colourless, translucent layer. The layer applied to the cleaned surface of the substrate is preferably a sol-gel paint, particularly a sol-gel paint consisting of a polysiloxane and advantageously a sol-gel paint consisting of a polysiloxane produced from an alcoholic silane solution, particularly an alkoxysilane solution, and an aqueous colloidal silicic acid solution. In this context, polysiloxane refers to polymers of crosslinked siloxanes. The polysiloxane is particularly produced by a condensation reaction between hydrolysed and crosslinkable silanes, particularly alkoxysilanes, and colloidal silicic acid.

The condensation reaction between hydrolysed silanes, particularly alkoxysilanes, with each other, and hydrolysed silanes, particularly alkoxysilanes, and colloidal silicic acid results in the formation of an inorganic network of polysiloxanes. At the same time, organic groups, particularly alkyl groups or simple alkyl groups, are incorporated in the inorganic network via carbon compounds. However, the organic groups, or alkyl groups, do not participate directly in the polymerisation or crosslinking of the siloxanes, that is to say they are not used to form an organic polymer system, but only to functionalise it. The function consists in that the organic groups, particularly the alkyl groups, are attached to the outsides of the polysiloxanes during the sol-gel process and thereby form a layer that is water-repellent on the outside, and which lends the sol-gel paint a strongly hydrophobic property.

As was mentioned, through controlled hydrolysis and condensation of silicon alkoxides and silica acid the sol-gel process described results in a sol-gel paint consisting of an inorganic network with integrated alkyl groups. The polysiloxanes obtained thereby must therefore be classified rather as inorganic polymers.

When preparing one preferred embodiment of a sol-gel paint as a protective layer, it is convenient to start from two base solutions A and B.

Solution A is an alcoholic solution of one or more different alkoxysilanes, wherein the alkoxysilanes are present in non-hydrolysed form in an anhydrous medium. It is convenient to use an alcohol, for example methyl, ethyl, propyl or butyl alcohol, and preferably isopropyl alcohol, as the solvent.

The alkoxysilanes are described with the general formula XₙSi(OR)₄₋ₙ, in which “R” is a simply alkyl, preferably from the group comprising methyl, ethyl, propyl and butyl. “X” is suitably also an alkyl, preferably from the group comprising methyl, ethyl, propyl and butyl. Suitable alkoxysilanes are for example tetramethoxysilane (TMOS) and preferably tetraethoxysilane (TEOS) and methyltrimethoxysilane (MTMOS) as well as other alkoxysilanes.

In a particularly preferred embodiment, solution A is prepared from tetraethoxysilane (TEOS) and/or methyltrimethoxysilane (MTMOS) with a methyl, ethyl or propyl alcohol and particularly with an isopropyl alcohol as the solvent. Solution A may contain for example 25-35% by mass (mass percentage), particularly 30% by mass, TEOS and 15-25% by mass, particularly 20% by mass, MTMOS, both of which are dissolved in 40-60% by mass, particularly 50% by mass, isopropyl alcohol.

Solution B contains colloidal silicic acid dissolved in water. In an advantageous variant, solution B is adjusted to a pH value between 2.0-4. preferably between 2.5-3.0 and particularly 2.5 with an acid, preferably nitric acid.

The silicic acid used is preferably a silicic acid that has been stabilized in an acid medium, the pH value of the silicic acid being advantageously between 2-4. The silicic acid is advantageously as low-alkali as possible. The alkali content (for example Na₂0) in the silicic acid is preferably less than 0.04% by mass.

Solution B contains for example 70-80% by mass, particularly 75% by mass, water as the solvent and 20-30% by mass, particularly 25% by mass, colloidal silicic acid. Solution B is advantageously adjusted to a pH value between 2.0-3.5, preferably between 2.5-3.0 and particularly 2.5 with nitric acid.

When the two base solutions A and B are combined and mixed in the presence of nitric acid, a hydrolysis reaction takes place between the water contained in solution B and the alkoxysilanes contained in solution A.

Hydrolysis reaction: Si(OR)ₙ+nH₂O→Si(OH)ₙ+nR(OH)

At the same time, a condensation reaction takes place, in which a siloxane bond (Si—O—Si) is formed from two Si—OH groups in each case, and water is split off. In this environment, as the polymerization progresses a network of polysiloxanes is created to which alkyl groups are joined. The new mixture solution is in a gel state.

The two solutions A and B are preferably mixed in a weight ratio of 7:3 parts.

The sol-gel paint is advantageously applied to the substrate or the corresponding surface in gel form, or isolated and then dried and cured. The drying process consists in desorbing the water and alcohols that remain in the sol-gel paint, so that the sol-gel paint is cured and a protective layer that is both corrosion-resistant and resistant to chemical substances forms on the surface of the metal film.

Coating is carried out advantageously in a continuous process, for example by application, spinning or sputtering, which is suitable for treating metal film in strip form. Particularly preferred coating processes are spraying, sputtering and dipping or dip coating.

Sol-gel systems that are marketed commercially for example under the brand name CERAPAINT by the company Akzo Nobel are particularly suitable for forming the protective layer.

Protective layers (sol-gel paints) that are produced by applying a sol-gel system, that is to say by coating the actual metal film substrate with a sol-gel system, must undergo a curing and/or drying process in which the sol-gel system is converted into the resistant sol-gel paint.

The substrate coated with the sol-gel paint is advantageously dried and cured by irradiation, such as UV radiation, electron radiation, laser radiation, or by thermal radiation, such as IR (infrared) irradiation, or by convection heating or a combination of such drying and/or curing methods.

Convection heating may be performed advantageously by exposing to heated gases such as air, nitrogen, inert gases or mixtures thereof. The sol-gel paint layer is preferably dried and cured by passing through a continuous furnace.

Further advantages, features and particularities of the invention will be evident from the following description of preferred embodiments and with reference to the drawing; the drawing includes shows diagrammatically in

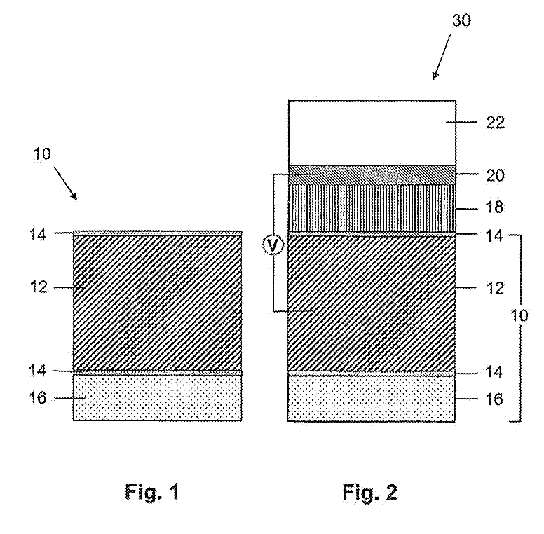

FIG. 1 a cross section through a substrate with protective layer;

FIG. 2 cross section through a photovoltaic cell constructed on the substrate of FIG. 1.

A substrate 10 shown in FIG. 1 comprises an aluminium film 12 having a thickness of for example 150 μm. The purity of the aluminium used to produce the film is for example Al 99.85. The film is rolled to produce a high-gloss finish and if necessary at least the side that is to serve as the basis for a photovoltaic absorber layer may also be polished electrolytically to create a surface that is as smooth as possible. Aluminium film 12 has a natural oxide layer 14 only a few nanometres thick on either side thereof. The side of aluminium film 12 that will subsequently form the rear of a photovoltaic cell is provided with a protective layer 16 of sol-gel paint having a thickness of for example 1-2 μm.

Having been rolled to a high-gloss finish, the aluminium film is degreased by dipping or spraying with an acid or alkaline solution to remove oxide films and surface contamination. The surface quality obtained is sufficient to allow the degreased aluminium surface to be coated directly with the sol-gel paint and to allow an absorber layer to be constructed directly thereon. However, the sol-gel layer may also be applied so a strip that has been anodised on one side for example.

On the basis of the substrate 10 shown in FIG. 1 in the form of an aluminium film 12 coated with a sol-gel paint, an absorber layer 18 is constructed directly on the smooth side of the aluminium film 12 facing protective layer 16 made from the sol-gel paint, which in this case forms the rear contact layer of the photovoltaic cell 30 shown in FIG. 2. The low thickness of natural oxide layer 14 enables absorber layer 18 to be constructed directly thereon without an additional contacting layer. A front contact layer 20 made from transparent material and covered by protective layer 22 made from a transparent plastic is arranged on absorber layer 18.

Protective layer 16 of the sol-gel paint protects aluminium film 12 from attack by chemicals and/or from corrosion by the fumes and gases that are formed as absorber layer 18 is manufactured and cured. In addition, protective layer 16 made from the sol-gel paint also helps to increase the mechanical strength of the aluminium film 12, which becomes soft under the effect of high temperatures.

1. A substrate comprising a metal film for producing photovoltaic cells, wherein a first side of the metal film is intended to accommodate a photovoltaic absorber layer, and further wherein,
a protective layer made from a silicon-based sol-gel paint is arranged on a second side of the metal film to improve chemical resistance and corrosion resistance thereof at an elevated temperature.

2. The substrate as claimed in claim 1, wherein said metal film is rolled to a yield a high-gloss finish and/or polished electrolytically to obtain a surface roughness Ra<100 nm (nanometres), optionally Ra<50 nm at least on the first side thereof.

3. The substrate as claimed in claim 1, wherein said protective layer has a thickness between 0.5 and 4 μm.

4. The substrate as claimed in claim 1, wherein said metal film is a film made from aluminium or an aluminium alloy.

5. A photovoltaic cell comprising a substrate as recited in claim 1.
